(19) United States
(12) Patent Application Publication
(10) Pub. No.: US 2025/0309086 A1
(43) Pub. Date: Oct. 2, 2025

(54) PACKAGE STRUCTURE AND METHOD FOR FORMING THE SAME

(71) Applicant: TAIWAN SEMICONDUCTOR MANUFACTURING COMPANY, LTD., Hsinchu (TW)

(72) Inventors: Chien-Hsun CHEN, Pingtung County (TW); Shu-Chun YANG, Changhua County (TW); Wei Chih CHEN, Hsinchu City (TW); Chien-Chun TSAI, Hsinchu County (TW); Shenggao LI, Cupertino, CA (US)

(73) Assignee: TAIWAN SEMICONDUCTOR MANUFACTURING COMPANY, LTD., Hsinchu (TW)

(21) Appl. No.: 18/623,579

(22) Filed: Apr. 1, 2024

(51) Int. Cl. H01L 23/498; H01L 21/48; H01L 21/56; H01L 23/00; H01L 25/10

(52) U.S. Cl. CPC H01L 23/49838; H01L 21/486; H01L 21/568; H01L 23/49833; H01L 25/105; H01L 23/49816; H01L 24/16; H01L 24/32; H01L 24/73; H01L 2224/16225; H01L 2224/32225; H01L 2224/73204; H01L 2924/1815

(57) ABSTRACT

A package structure includes a first die and a second die adjacent to the first die. A redistribution structure is above and electrically connected with the first and second die. The redistribution structure includes a first conductive line electrically connecting the first die to the second die, and a first conductive via in contact with the first conductive line and overlapping a die-to-die region between the first and second dies. A third die is over and electrically connected with the redistribution structure. An external connector is over electrically connected with the third die.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

As the demand for shrinking electronic devices has grown, a need for smaller and more creative packaging techniques of semiconductor dies has emerged. An example of such packaging systems is Package-on-Package (POP) technology. In a PoP device, a top semiconductor package is stacked on top of a bottom semiconductor package to provide a high level of integration and component density. Another example is a Chip-On-Wafer-On-Substrate (CoWoS) structure, where a semiconductor chip is attached to a wafer (e.g., an interposer) to form a Chip-On-Wafer (CoW) structure. The CoW structure is then attached to a substrate (e.g., a printed circuit board) to form a CoWoS structure. These and other advanced packaging technologies enable production of semiconductor devices with enhanced functionalities and small footprints.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a cross-sectional view of a package structure in accordance with some embodiments of the present disclosure.

FIGS. 1B and 1C illustrate top views of a package structure in accordance with some embodiments of the present disclosure.

FIGS. 2 to 9 illustrate a method in various stages of forming a package structure in accordance with some embodiments of the present disclosure.

FIG. 10A illustrates a cross-sectional view of a package structure in accordance with some embodiments of the present disclosure.

FIG. 10B illustrates a top view of a package structure in accordance with some embodiments of the present disclosure.

FIG. 11 illustrates a cross-sectional view of a package structure in accordance with some embodiments of the present disclosure.

FIG. 12 illustrates a cross-sectional view of a package structure in accordance with some embodiments of the present disclosure.

FIG. 13A illustrates a cross-sectional view of a package structure in accordance with some embodiments of the present disclosure.

FIGS. 13B and 13C illustrate top views of a package structure in accordance with some embodiments of the present disclosure.

FIGS. 14 to 21 illustrate a method in various stages of forming a package structure in accordance with some embodiments of the present disclosure.

FIG. 22A illustrates a cross-sectional view of a package structure in accordance with some embodiments of the present disclosure.

FIG. 22B illustrates a top view of a package structure in accordance with some embodiments of the present disclosure.

FIG. 23 illustrates a cross-sectional view of a package structure in accordance with some embodiments of the present disclosure.

FIG. 24 illustrates a cross-sectional view of a package structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

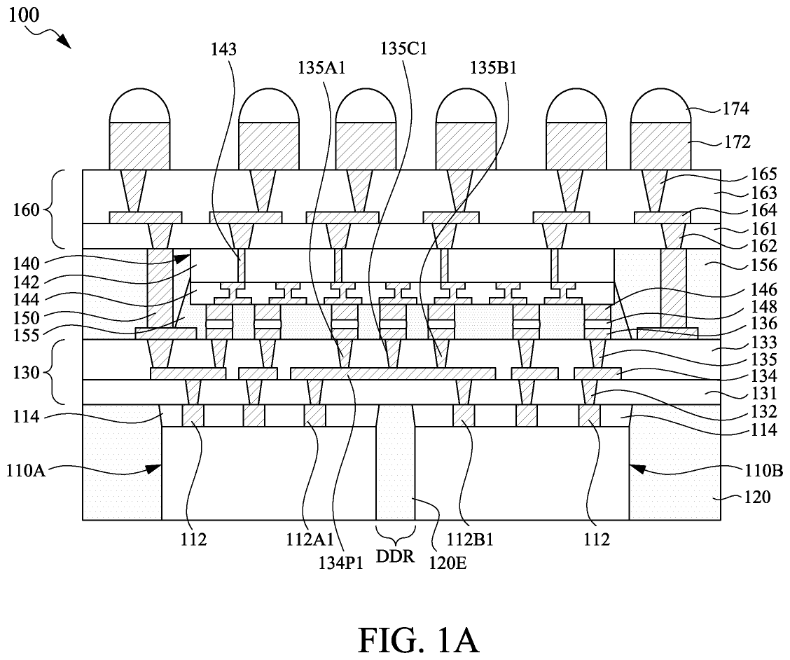

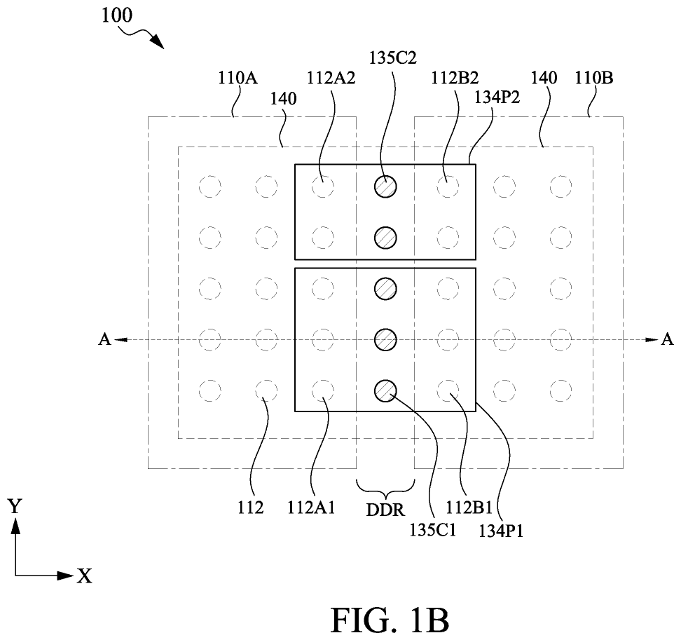

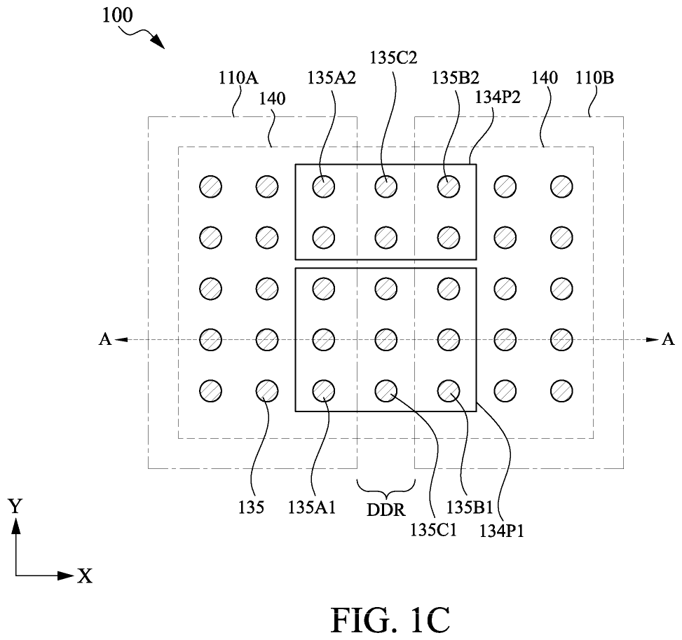

FIG. 1A illustrates a cross-sectional view of a package structure in accordance with some embodiments of the present disclosure. FIGS. 1B and 1C illustrates top views of a package structure in accordance with some embodiments of the present disclosure. In greater detail, FIG. 1A is a cross-sectional view along line A-A of FIGS. 1B and 1C. It is noted that some elements of FIG. 1A are not illustrated in FIGS. 1B and 1C for brevity.

Shown there is a package structure 100. The package structure 100 includes a plurality of dies 110A and 110B. Each of the 110A and 110B includes a semiconductor substrate 111. In some embodiments, the semiconductor substrate 111 includes a crystalline silicon substrate. The dies 110A and 110B may include a plurality of conductive features 112 that are embedded in a dielectric layer 114, in which top surfaces of the conductive features 112 are exposed through the dielectric layer 114, and are substantially level with top surface of the dielectric layer 114.

In some embodiments, the conductive features 112 may include metal such as copper, copper alloy, aluminum, aluminum alloy, or combinations thereof. Here, the term “copper” may include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc. The dielectric layer 114 may include a low-K dielectric material or an extreme low-K (ELK) material, such as an oxide, silicon dioxide, borophosphosilicate glass (BPSG), phosphosilicate glass (PSG), fluorinated silicate glass (FSG), SiOxCy, Spin-On-Glass, Spin-On-Polymers, silicon carbon material, compounds thereof, composites thereof, combinations thereof, or the like.

In some embodiments, the dies 110A and 110B each may be a package die, a device die, a die stack, and/or the like. The device die may be high performance integrated circuit, such as a System-on-Chip (SoC) die, a Central Processing Unit (CPU) die, a Graphic Processing Unit (GPU) die, field-programmable gate array (FPGA) die, a mobile application die, a memory die, or a die stack. In some embodiments, the memory die is a memory cube such as High Bandwidth Memory (HBM) die. In some embodiments, the dies 110A and 110B are both SoC dies.

The package structure 100 further includes a molding compound 120 that encapsulates the dies 110A and 110B. In some embodiments, top surfaces and bottom surfaces of the dies 110A and 110B may be exposed through the molding compound 120. In greater detail, top surfaces of the conductive features 112 and the dielectric layer 114 are substantially level with top surface of the molding compound 120. The molding compound 120 has a portion 120E laterally between the dies 110A and 110B. Stated another way, the portion 120E of the molding compound 120 is disposed at a die-to-die region DDR between the dies 110A and 110B. Here, the “die-to-die region” may be referred to as a region between the end point (sidewall) of the die 110A closest to the die 110B and the end point (sidewall) of the die 110B closest to the die 110A.

The molding compound 120 may be, for example, a molding compound such as a resin, polyimide, PPS, PEEK, PES, epoxy molding compound (EMC), another material, the like, or a combination thereof. In other embodiments, the molding compound 120 may be a composite material including a base material (such as polymer) and a plurality of fillers distributed in the base material. In some embodiments, the base material includes resins, such as epoxy resins, phenolic resins or silicon-containing resins, or the like or combinations thereof. The fillers may include a single element, a compound such as nitride, oxide, or a combination thereof. The fillers may include silicon oxide, aluminum oxide, boron nitride, alumina, silica, or the like, for example. In some embodiments, the fillers may be spherical filler particles.

The package structure 100 further includes a redistribution structure 130 over the dies 110A and 110B and the molding compound 120. In greater detail, the redistribution structure 130 is disposed along top surfaces of the molding compound 120 and the dies 110A and 110B. The redistribution structure 130 may include a dielectric layer 131, conductive vias 132, a dielectric layer 133, conductive lines 134, conductive vias 135, and conductive pads 136. The dielectric layer 131 is in direct contact with the molding compound 120 and the dielectric layer 114 of the dies 110A and 110B. The conductive vias 132 are disposed in the dielectric layer 131 and in contact with the respective conductive features 112 in the dies 110A and 110B. The dielectric layer 133 is disposed over and in contact with the dielectric layer 131. The conductive lines 134 and the conductive vias 135 are disposed in the dielectric layer 133. The conductive lines 134 extend along top surface of the dielectric layer 131 and are in contact with the respective conductive vias 132. The conductive vias 135 are over and in contact with the respective conductive lines 134. The conductive pads 136 extend along top surface of the dielectric layer 133 and are in contact with the respective conductive vias 135. In some embodiments, the redistribution structure 130 includes a single layer of conductive lines (e.g., the conductive lines 134).

Here, the term “conductive via” may be a conductive structure having longest dimensions extending vertically, and the term “conductive line” may be a conductive structure having longest dimensions extending laterally. For example, the conductive via conduct current vertically and are used to electrically connect two conductive features at vertically adjacent levels, whereas the conductive line conduct current laterally and are used to distribute electrical signals and power within one level.

In some embodiments, the conductive vias 132, the conductive lines 134, the conductive vias 135, and the conductive pads 136 may include metal such as copper, copper alloy, aluminum, aluminum alloy, or combinations thereof. The dielectric layers 131 and 133 may include a low-K dielectric material or an extreme low-K (ELK) material, such as an oxide, silicon dioxide, borophosphosilicate glass (BPSG), phosphosilicate glass (PSG), fluorinated silicate glass (FSG), SiOxCy, Spin-On-Glass, Spin-On-Polymers, silicon carbon material, compounds thereof, composites thereof, combinations thereof, or the like.

The package structure 100 further includes a die 140 disposed over the redistribution structure 130 and electrically connected with the redistribution structure 130. In some embodiments, the die 140 is a large-scale integration (LSI) circuit die, a very large-scale integration (VLSI) circuit die, or the like. In some embodiments, the die 140 may include a greater chip size than the dies 110A and 110B. For example, a width of the die 140 may be wider than widths of the dies 110A and 110B.

The die 140 includes a semiconductor substrate 142 and an interconnect structure 144. In some embodiments, the semiconductor substrate 142 includes a crystalline silicon substrate. In some alternative embodiments, the semiconductor substrate 142 is made of some other suitable elemental semiconductor, such as diamond or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide. The interconnect structure 144 may include interconnect wirings (e.g., copper interconnect wirings) and dielectric layer stacked alternately, wherein the interconnect wirings of the interconnect structure 144 are electrically connected with the active components and/or the passive components in the semiconductor substrate 142. The interconnect structure 144 is formed through back end of line (BEOL) fabrication processes. The die 140 further includes through vias 143 penetrating through the semiconductor substrate 142 and electrically connected with the interconnect structure 144. In some embodiments, the through vias 143 may include metal such as copper, copper alloy, aluminum, aluminum alloy, or combinations thereof. In some embodiments, the through vias 143 may also be referred to as through silicon vias (TSVs).

The die 140 further includes under bump metallizations (UBMs) 146 along bottom surface of the interconnect structure 144 of the die 140, and are electrically connected with the interconnect structure 144. In some embodiments, the UBMs 146 are copper pillars, or other suitable materials, such as solder, aluminum, gold, nickel, silver, palladium, tin, the like, or a combination thereof. Bumps 148 are connected with the bottom surfaces of the respective UBMs 146. In greater detail, the UBMs 146 are electrically connected with the respective conductive pads 136 of the redistribution structure 130 through the bumps 148. In some embodiments, the bumps 148 may be ball grid array (BGA) connectors, solder bumps, controlled collapse chip connection (C4) bumps, micro bumps (e.g., ubumps), electroless nickel-electroless palladium-immersion gold technique (ENEPIG) formed bumps, or the like.

The package structure 100 further includes conductive vias 150 adjacent to the die 140 and are over and in contact with the respective conductive pads 136 of the redistribution structure 130. The conductive vias 150 may include copper, titanium, tungsten, aluminum, another metal, the like, or a combination thereof. In some embodiments, the conductive vias 150 can also be referred to as through mold vias (TMVs).

The package structure 100 further includes an underfill material 155 dispensed into the gaps between the die 140 and the redistribution structure 130. The underfill material 155 surrounds the UBMs 146, the bumps 148, and the conductive pads 136, and may extend up along sidewalls of the die 140. The underfill material 155 may be acceptable material, such as a polymer, epoxy, molding underfill, or the like.

The package structure 100 further includes a molding compound 156 encapsulating the conductive vias 150 and the die 140. The molding compound 156 may be, for example, a molding compound such as a resin, polyimide, PPS, PEEK, PES, epoxy molding compound (EMC), another material, the like, or a combination thereof. In other embodiments, the molding compound 156 may be a composite material including a base material (such as polymer) and a plurality of fillers distributed in the base material. In some embodiments, the base material includes resins, such as epoxy resins, phenolic resins or silicon-containing resins, or the like or combinations thereof. The fillers may include a single element, a compound such as nitride, oxide, or a combination thereof. The fillers may include silicon oxide, aluminum oxide, boron nitride, alumina, silica, or the like, for example. In some embodiments, the fillers may be spherical filler particles.

The package structure 100 further includes a redistribution structure 160 disposed over the die 140 and the molding compound 156. In greater detail, the redistribution structure 160 is disposed along top surfaces of the molding compound 156 and the die 140. The redistribution structure 160 may include a dielectric layer 161, conductive vias 162, a dielectric layer 163, conductive lines 164, and conductive vias 165. The dielectric layer 161 is in direct contact with the molding compound 156 and the die 140. The conductive vias 162 are disposed on the dielectric layer 161 and in contact with the respective conductive vias 150 and the through vias 143 in the die 140. The dielectric layer 163 is disposed over and in contact with the dielectric layer 161. The conductive lines 164 and the conductive vias 165 are disposed in the dielectric layer 163. The conductive lines 164 extend along top surface of the dielectric layer 161 and are in contact with the respective conductive vias 162. The conductive vias 165 are over and in contact with the respective conductive lines 164. The conductive pads 166 extend along top surface of the dielectric layer 163 and are in contact with the respective conductive vias 165. In some embodiments, the redistribution structure 160 includes a single layer of conductive lines (e.g., the conductive lines 164), while the disclosure is not limited thereto. In other embodiments, the redistribution structure 160 may include suitable number of dielectric layers, conductive vias, and conductive lines.

The package structure 100 further includes UBMs 172 over the redistribution structure 160 and electrically connected with the respective conductive features (e.g. conductive vias 165) in the redistribution structure 160. In some embodiments, the UBMs 172 are copper pillars, or other suitable materials, such as solder, aluminum, gold, nickel, silver, palladium, tin, the like, or a combination thereof. Bumps 174 are disposed over the respective UBMs 146. In some embodiments, the bumps 174 may be ball grid array (BGA) connectors, solder bumps, controlled collapse chip connection (C4) bumps, micro bumps (e.g., ubumps), electroless nickel-electroless palladium-immersion gold technique (ENEPIG) formed bumps, or the like. In some embodiments, each bump 174 and the respective UBM 146 may be collectively referred to as an external connector.

Reference is made to FIGS. 1A, 1B, and 1C. In greater detail, FIG. 1B shows a structural relationship among the dies 110A and 110B, the conductive features 112 in the dies 110A and 110B, the die 140, the conductive lines 134 in the redistribution structure 130, and the conductive vias 135 in the redistribution structure 130. FIG. 1C shows a structural relationship among the dies 110A and 110B, the die 140, the conductive lines 134 in the redistribution structure 130, and the conductive vias 135 in the redistribution structure 130.

The conductive lines 134 of the redistribution structure 130 include a conductive line 134P1 and a conductive line 134P2 each overlapping both the dies 110A and 110B. Stated another way, each of the conductive lines 134P1 and 134P2 extends from a first position vertically above the die 110A, passing through the die-to-die region DDR between the dies 110A and 110B, to a second position vertically above the die 110B.

The conductive line 134P1 vertically overlaps and is electrically connected with the conductive features 112A1 in the die 110A through the respective conductive vias 132. On the other hand, the conductive line 134P1 vertically overlaps and is electrically connected with the conductive features 112B1 in the die 110B through the respective conductive vias 132. Similarly, the conductive line 134P2 vertically overlaps and is electrically connected with the conductive features 112A2 in the die 110A through the respective conductive vias 132. On the other hand, the conductive line 134P2 vertically overlaps and is electrically connected with the conductive features 112B2 in the die 110B through the respective conductive vias 132. That is, the dies 110A and 110B may be electrically connected with each other through the conductive line 134P1 and the conductive features 112 and the conductive vias 132. Alternatively, the dies 110A and 110B may be electrically connected with each other through the conductive line 134P2 and the conductive features 112 and the conductive vias 132.

The conductive features 112A1 and 112A2 in the die 110A are arranged along a first direction (e.g., Y-direction), and the conductive features 112B1 and 112B2 in the die 110B are arranged along the first direction (e.g., Y-direction). In some embodiments, the conductive features 112 in the die 110A may include several rows of conductive features 112 arranged along a second direction (e.g., X-direction), and the conductive features 112A1 and 112A2 in the die 110A are at a row that is closest to the die 110B. Similarly, the conductive features 112 in the die 110B may include several rows of conductive features 112 arranged along a second direction (e.g., X-direction), and the conductive features 112B1 and 112B2 in the die 110B are at a row that is closest to the die 110A. It is understood that the first direction (e.g., Y-direction) is substantially perpendicular to the second direction (e.g., X-direction).

With respect to the conductive vias 135, the conductive vias 135 may include conductive vias 135A1 vertically above the conductive line 134P1 and overlapping the die 110A, and conductive vias 135A2 vertically above the conductive line 134P2 and overlapping the die 110A, in which the conductive vias 135A1 and 135A2 may be arranged in a row along the first direction (e.g., Y-direction). The conductive vias 135 also include conductive vias 135B1 vertically above the conductive line 134P1 and overlapping the die 110B, and conductive vias 135B2 vertically above the conductive line 134P2 and overlapping the die 110B, in which the conductive vias 135B1 and 135B2 may be arranged in a row along the first direction (e.g., Y-direction).

Moreover, the conductive vias 135 also include conductive vias 135C1 vertically above the conductive line 134P1 and overlapping the die-to-die region DDR, and conductive vias 135C2 vertically above the conductive line 134P2 and overlapping the die-to-die region DDR, in which the conductive vias 135C1 and 135C2 may be arranged in a row along the first direction (e.g., Y-direction). In some embodiments, the conductive vias 135C1 and 135C2 do not overlap the dies 110A and 110B. In some embodiments, the number of the conductive vias 135C1 is different from the number of the conductive vias 135C2. For example, in the illustrated embodiments, there are three conductive vias 135C1 and two conductive vias 135C2, while the disclosure is not limited thereto. In other embodiments, the number of the conductive vias 135C1 may be the same as the number of the conductive vias 135C2.

In some embodiments, the conductive vias 135C1 are substantially aligned with the conductive vias 135A1 and 135B1 along the second direction (e.g., X-direction), and the conductive vias 135C2 are substantially aligned with the conductive vias 135A2 and 135B2 along the second direction (e.g., X-direction).

Although not illustrated, it is noted that the conductive pads 136, the bumps 148, and the UBMs 146 may also include a same arrangement as the conductive vias 135 discussed with respect to FIGS. 1B and 1C. That is, the conductive pads 136, the bumps 148, and the UBMs 146 may also include portions that correspond to the conductive vias 135A1, 135A2, 135B1, 135B2, 135C1, and 135C2 as discussed in FIG. 1C. Accordingly, relevant details will not be repeated for brevity.

Based on the above discussion, it can be seen that the dies 110A and 110B (at the bottom side of the package structure 100) may be electrically connected with the bumps 174 (at the top side of the package structure 100) through several conductive structures, such as the conductive features 112, the redistribution structure 130, the bumps 148, the die 140, and the redistribution structures 160. Accordingly, electrical signal may be conducted from an external device down to the dies 110A and 110B. However, as device scale getting smaller and smaller, electromigration (EM) issue may likely occur in the package structure, resulting in a deteriorated performance to the package structure. Embodiments of the present disclosure provide a package structure by forming additional conductive vias (e.g., conductive vias 135C1 and 135C2) and corresponding bumps vertically overlapping a die-to-die region between the dies (e.g., the dies 110A and 110B). The additional conductive vias and bumps may provide more current paths in the package structure, so as to address the electromigration issue. As a result, performance of the package structure may be improved.

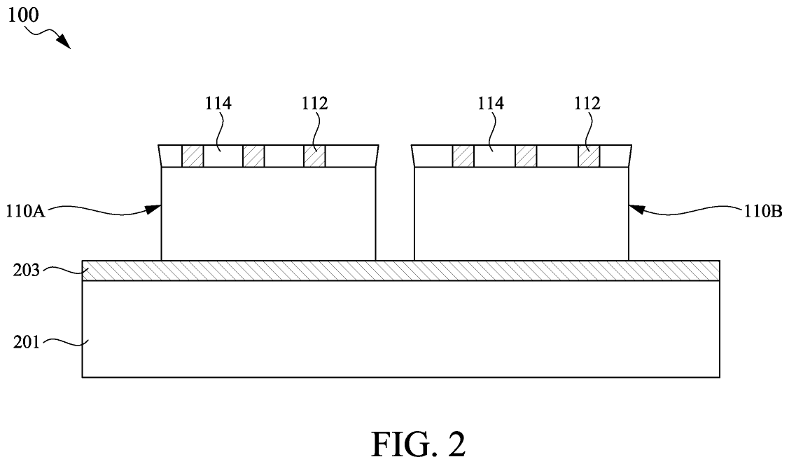

FIGS. 2 to 9 illustrate a method in various stages of forming a package structure in accordance with some embodiments of the present disclosure. In greater detail, 2 to 9 illustrate a method for forming the package structure 100 as discussed in FIGS. 1A to 1C. Although FIGS. 2 to 9 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

Reference is made to FIG. 2. Shown there is a carrier substrate 201, and a release film 203 is formed over the carrier substrate 201. In some embodiments, the carrier substrate 201 includes glass, ceramic, or other suitable material to provide structural support during the formation of various features in device package. The release film 203 may be formed of a polymer-based material, which may be removed along with the carrier substrate 201 in subsequent operations. In some embodiments, the release film 203 is an epoxy-based thermal-release material, which loses its adhesive property when heated, such as a light-to-heat conversion (LTHC) release coating. In some embodiments, the release film 203 may be an ultraviolet (UV) glue, which loses its adhesive property when exposed to UV light. The release film 203 can be a liquid that is dispensed and cured, a laminate film that is disposed onto the carrier substrate 201, or a layer of another form and method of disposition.

Dies 110A and 110B are attached to the release film 203. The dies 110A and 110B may include semiconductor devices or integrated circuits that have been previously manufactured on a semiconductive substrate. The semiconductor dies dies 110A and 110B may comprise one or more layers of electrical circuitry and/or electronic functions formed thereon, and may include conductive lines, vias, capacitors, diodes, transistors, resistors, inductors, and/or other electrical components, for example (not shown). In some embodiments, the dies 110A and 110B have been singulated from the substrate they were manufactured on and are ready for packaging. A pick and place machine may be used to place the dies 110A and 110B in predetermined locations on the carrier substrate 201, for example. The bottom surfaces of the dies 110A and 110B are attached to the release film 203. In some embodiments, the conductive features 112 of the dies 110A and 110B are exposed through the top surfaces of the dies 110A and 110B, respectively.

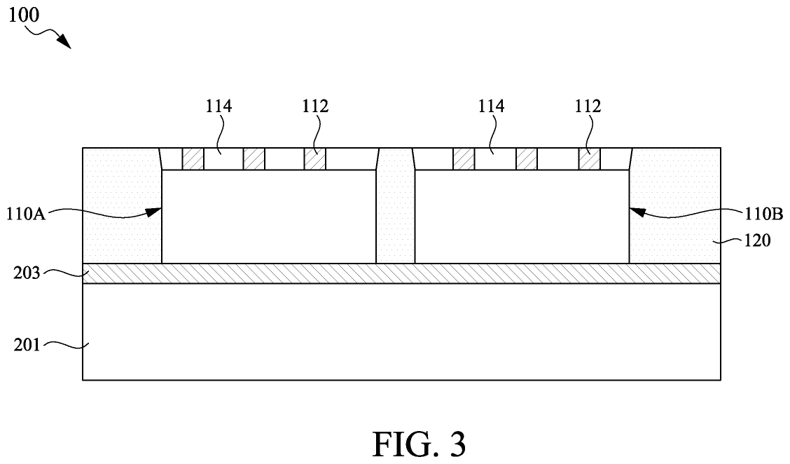

Reference is made to FIG. 3. A molding compound 120 may be molded onto the release film 203 over the carrier substrate 201 and surrounding the dies 110A and 110B. The top surface of molding compound 120 may be formed higher than, level with, or slightly lower than, top surfaces of the dies 110A and 110B. A grinding process may be performed to planarize the dies 110A and 110B, so that any unevenness in the top surfaces of the dies 110A and 110B may be at least reduced, and possibly substantially eliminated. If the molding compound 120 includes portions over the dies 110A and 110B, these portions of molding compound 120 may also be removed by the grinding process. Accordingly, the top surfaces of the remaining portions of the molding compound 120 are level with top surfaces of the dies 110A and 110B, and the conductive features 112 of the dies 110A and 110B are exposed after the grinding process is complete.

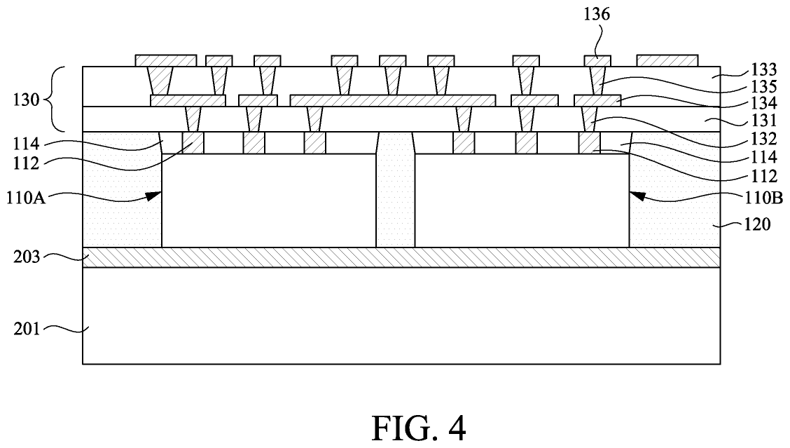

Reference is made to FIG. 4. A redistribution structure 130 is then formed over the molding compound 120 and the dies 110A and 110B. In some embodiments, the redistribution structure 130 may be formed by, for example, depositing a dielectric layer 131 over the molding compound 120 and the dies 110A and 110B. The dielectric layer 131 is then patterned to form openings that expose the corresponding conductive features 112 of the dies 110A and 110B. A first conductive layer is deposited along the patterned dielectric layer 131 and filling the opening of the patterned dielectric layer 131. The first conductive layer is then patterned according to a predetermined pattern, and the remaining portions of the first conductive layer constitute the conductive vias 132 and the conductive lines 134. Afterwards, a dielectric layer 133 is deposited over the dielectric layer 131. The dielectric layer 133 is then patterned to form openings that expose the corresponding conductive lines 134. A second conductive layer is deposited along the patterned dielectric layer 133 and filling the opening of the patterned dielectric layer 133. The second conductive layer is then patterned according to a predetermined pattern, and the remaining portions of the second conductive layer constitute the conductive vias 135 and the conductive pads 136.

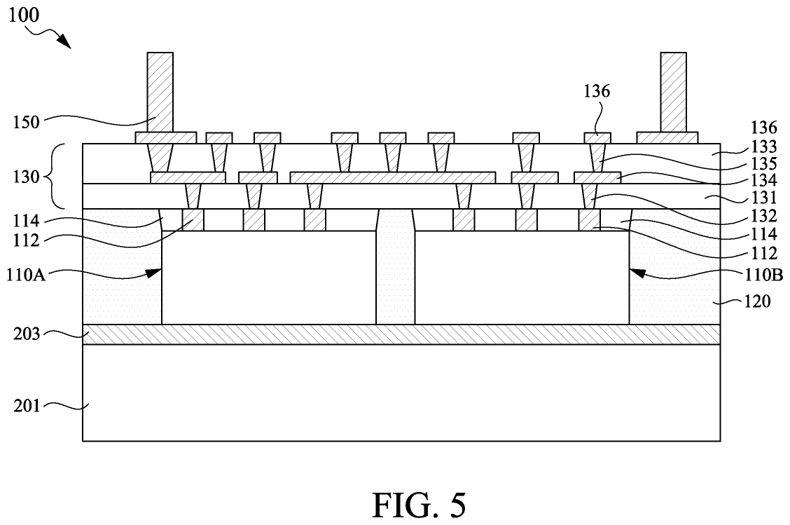

Reference is made to FIG. 5. Conductive vias 150 are formed over the respective conductive pads 136. In some embodiments, the conductive vias 150 may be formed by initially depositing a photoresist (not shown) over the redistribution structure 130. Once the photoresist has been formed, it may be patterned to form openings that expose portions of the conductive pads 136 that are located where the conductive vias 150 will subsequently be formed. Once the photoresist has been patterned, a conductive material may be deposited in the openings and over the conductive pads 136. The conductive material may be formed through a deposition process such as electroplating, electroless plating, or the like. However, while the material and methods discussed are suitable to form the conductive material, these are merely examples. Any other suitable materials or any other suitable processes of formation, such as CVD or PVD, may also be used to form the conductive vias 150. Once the conductive material has been formed, the photoresist may be removed through a suitable removal process such as an ashing process or a chemical stripping process, such as using oxygen plasma or the like.

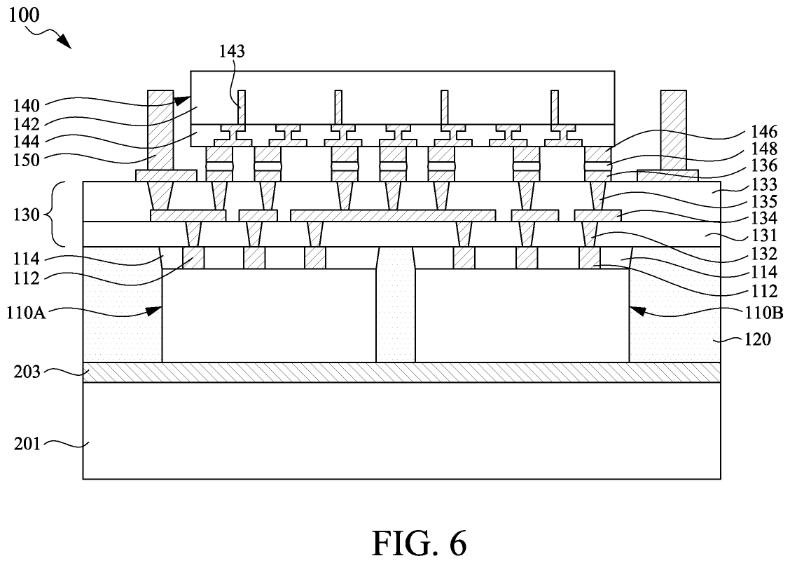

Reference is made to FIG. 6. A die 140 is attached to the redistribution structure 130. In some embodiments, the bumps 148 may first be formed on the UBMs 146 of the die 140. Then, the die 140 may be placed on the redistribution structure 130, for example, using e.g., a pick-and-place process. In some embodiments, once the bumps 148 on the UBMs 146 of the die 140 are attached on and are in physical contact with the corresponding conductive pads 136 of the redistribution structure 130, a reflow process may be performed to bond the bumps 148 to the conductive pads 136 of the redistribution structure 130 and thus attach the die 140 to the redistribution structure 130.

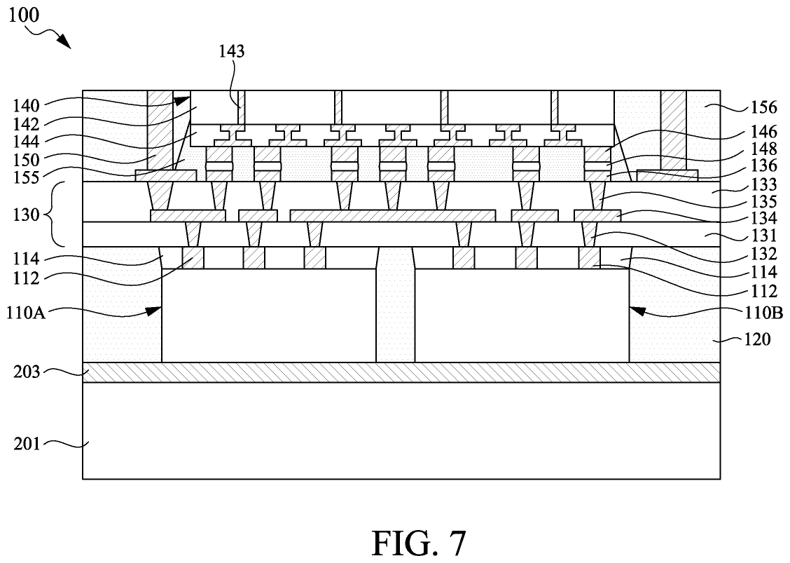

Reference is made to FIG. 7. Once the die 140 is attached to the redistribution structure 130, an underfill material 155 can be deposited in the gap between die 140 and the redistribution structure 130. The underfill material 155 can protect the conductive pads 136, the UBMs 146, the bumps 148, and provide structural support for the die 140. In some embodiments, the underfill material 155 may be cured after deposition. A molding compound 156 is formed to encapsulate of the die 140 and the conductive vias 150. The encapsulation may be performed using a molding device or the molding compound 156 may be deposited using another technique.

A planarization process is then performed on the molding compound 156. The planarization process may be performed, e.g., using a mechanical grinding process, a chemical mechanical polishing (CMP) process, or the like. The planarization process removes excess portions of molding compound 156 and exposes the conductive vias 150. The planarization process may also expose the through vias 143 in the die 140. After the planarization process is complete, the conductive vias 150 and/or the through vias 143 may have top surfaces level with a surface of the molding compound 156.

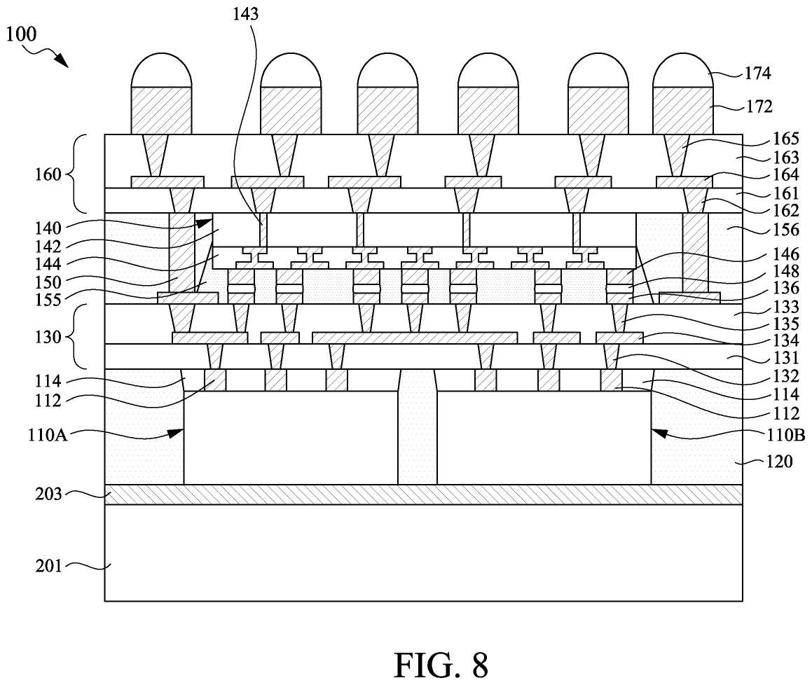

Reference is made to FIG. 8. A redistribution structure 160 is then formed over the molding compound 156 and the die 140. In some embodiments, the redistribution structure 160 may be formed by, for example, depositing a dielectric layer 161 over the molding compound 156 and the die 140. The dielectric layer 131 is then patterned to form openings that expose the corresponding conductive vias 150 and through vias 143 in the die 140. A first conductive layer is deposited along the patterned dielectric layer 161 and filling the opening of the patterned dielectric layer 161. The first conductive layer is then patterned according to a predetermined pattern, and the remaining portions of the first conductive layer constitute the conductive vias 162 and the conductive lines 164. Afterwards, a dielectric layer 163 is deposited over the dielectric layer 161. The dielectric layer 163 is then patterned to form openings that expose the corresponding conductive lines 164. A second conductive layer is deposited along the patterned dielectric layer 163 and filling the opening of the patterned dielectric layer 163. The second conductive layer is then patterned according to a predetermined pattern, and the remaining portions of the second conductive layer constitute the conductive vias 165 and the UBMs 172.

Bumps 174 are then formed over the UBMs 172. In some embodiments, the bumps 174 are formed by initially forming a layer of solder through evaporation, electroplating, printing, solder transfer, ball placement, or the like. Once a layer of solder has been formed on the UBMs 172, a reflow may be performed in order to shape the material into the desired shapes.

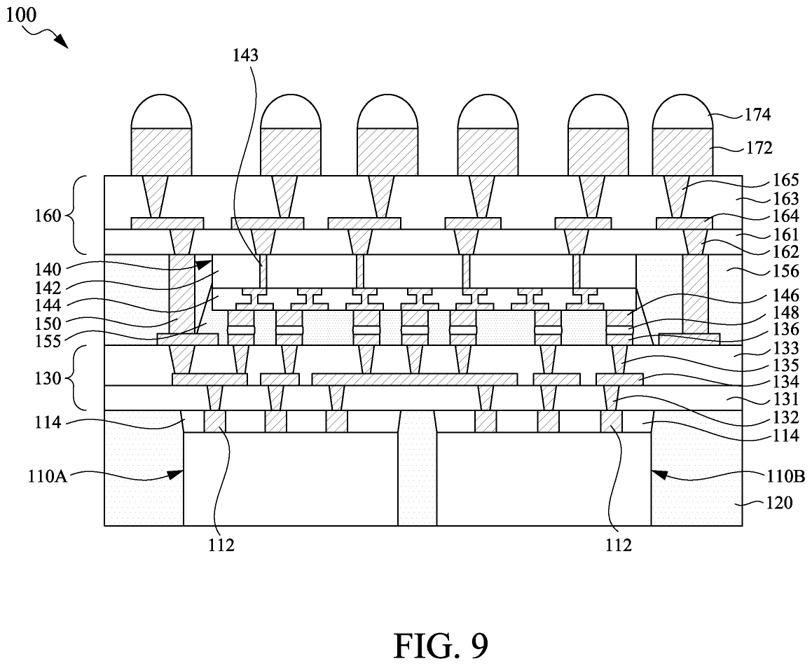

Reference is made to FIG. 9. The carrier substrate 201 is de-bonded from the molding compound 120. In some embodiments, the de-bonding process includes projecting a light such as a laser light or an UV light on the release film 203 over the carrier substrate 201 so that the release film 203 decomposes under the heat of the light and the carrier substrate 201 can be removed.

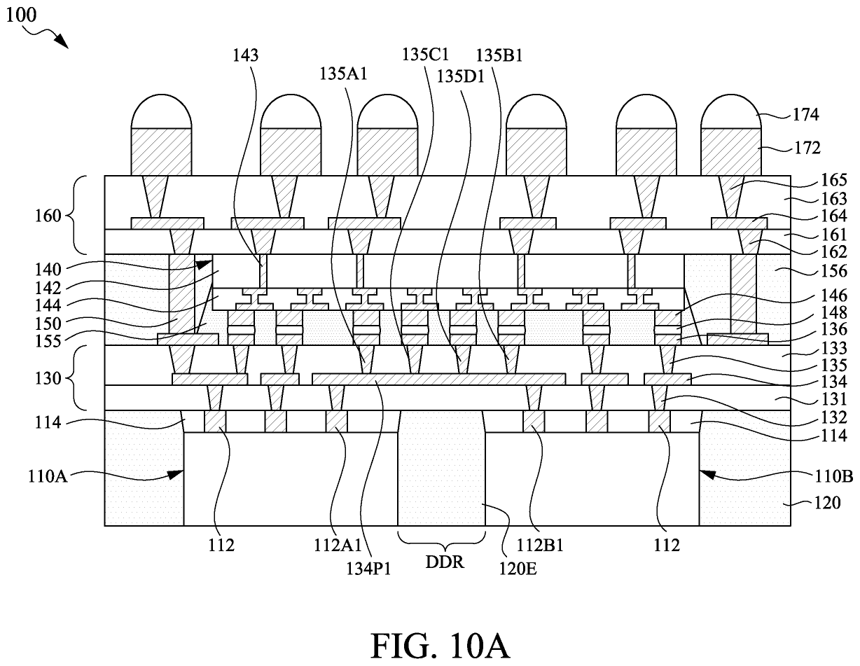

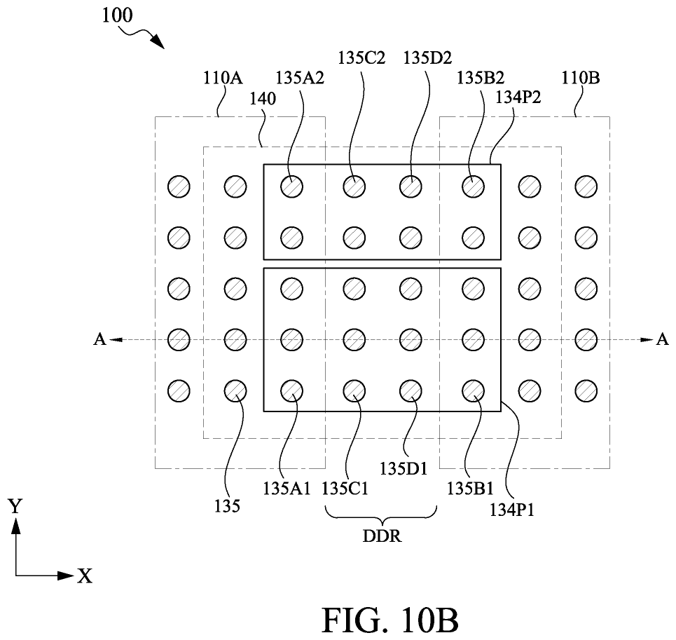

FIG. 10A illustrates a cross-sectional view of a package structure in accordance with some embodiments of the present disclosure. FIG. 10B illustrates a top view of a package structure in accordance with some embodiments of the present disclosure. In greater detail, FIG. 10A is a cross-sectional view along line A-A of FIG. 10B. It is noted that some elements of FIG. 10A are not illustrated in FIG. 10B for brevity. FIG. 10A is similar to the cross-sectional view of FIG. 1A, and FIG. 10B is a top view similar to FIG. 1C, thus similar elements are labeled the same and will not be repeated again.

The embodiments of FIGS. 10A and 10B are different from the embodiments of FIGS. 1A to 1C, in that the conductive vias 135 further include a row of conductive vias 135D1 and 135D2 vertically above the die-to-die region DDR. In greater detail, the conductive vias 135D1 are vertically above the conductive line 134P1, and the conductive vias 135D2 are vertically above the conductive line 134P2, respectively. In some embodiments, the row of conductive vias 135C1 and 135C2 and the row of conductive vias 135D1 and 135D2 are arranged along the second direction (e.g. X-direction). It is noted that, the number of rows of the conductive vias 135 at the die-to-die region DDR may depend on the area of the die-to-die region DDR. For example, more rows of the conductive vias 135 may also be applied for a larger die-to-die region DDR. The increasing number of conductive vias 135 may also be helpful to address the electromigration issue.

Although not illustrated, it is noted that the conductive pads 136, the bumps 148, and the UBMs 146 may also include a same arrangement as the conductive vias 135 discussed with respect to FIGS. 10A and 10B. That is, the conductive pads 136, the bumps 148, and the UBMs 146 may also include portions that correspond to the conductive vias 135A1, 135A2, 135B1, 135B2, 135C1, 135C2, 135D1, and 135D2 as discussed in FIG. 10B. Accordingly, relevant details will not be repeated for brevity.

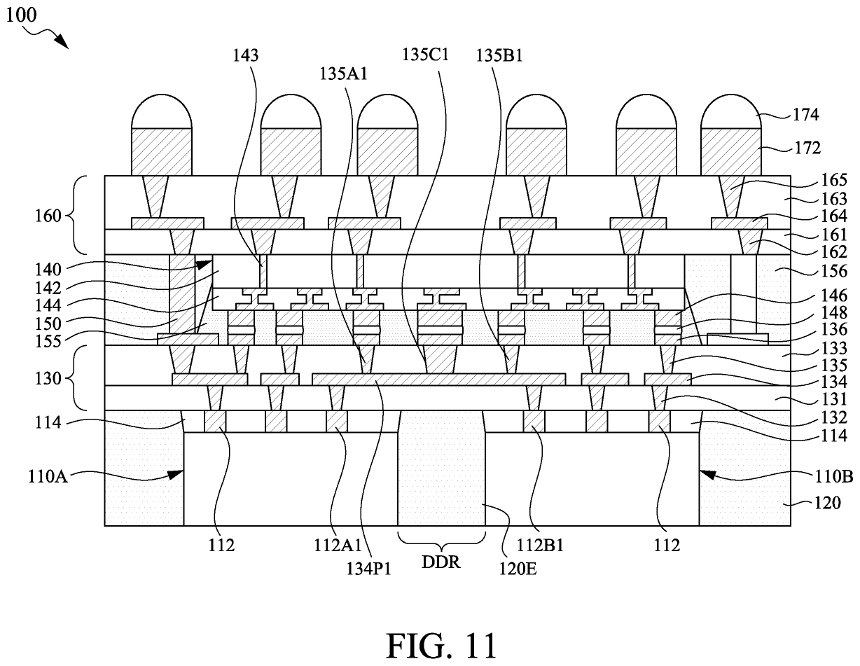

FIG. 11 illustrates a cross-sectional view of a package structure in accordance with some embodiments of the present disclosure. FIG. 11 is similar to the cross-sectional view of FIG. 1A, thus similar elements are labeled the same and will not be repeated again.

The embodiments of FIG. 11 are different from the embodiments of FIGS. 1A to 1C, in that the size of the conductive vias 135C1 (and 135C2, see FIG. 1C) vertically above the die-to-die region DDR may be different from the size of the conductive vias 135 outside the die-to-die region DDR. For example, the size (e.g., diameter or lateral width) of the conductive vias 135C1 and 135C2 may be greater than the conductive vias 135 that are vertically above the dies 110A and 110B. The increasing size of conductive vias 135C1 and 135C2 may provide enlarged current path, and may also be helpful to address the electromigration issue.

Although not illustrated, it is noted that the conductive pads 136, the bumps 148, and the UBMs 146 may also include a similar arrangement as the conductive vias 135 discussed with respect to FIG. 11. Accordingly, relevant details will not be repeated for brevity.

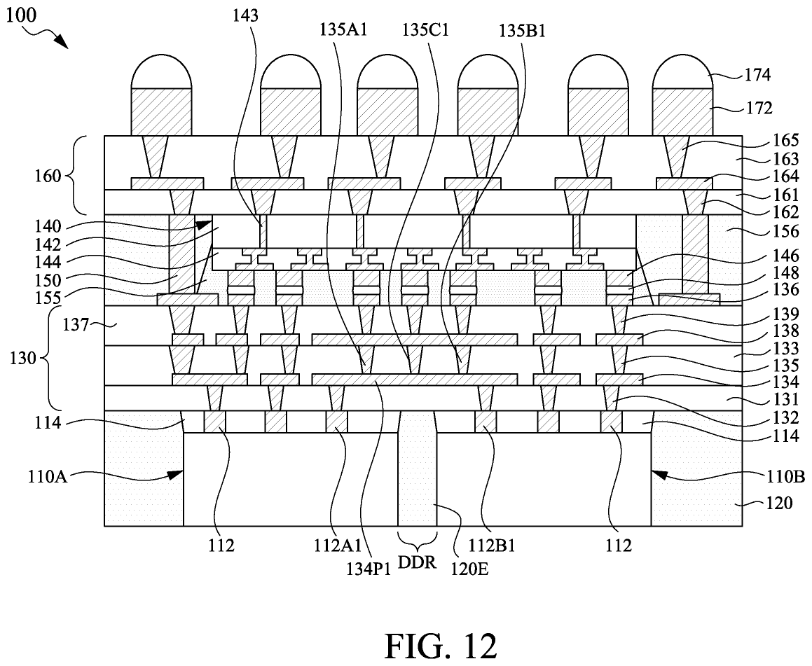

FIG. 12 illustrates a cross-sectional view of a package structure in accordance with some embodiments of the present disclosure. FIG. 12 is similar to the cross-sectional view of FIG. 1A, thus similar elements are labeled the same and will not be repeated again.

The embodiments of FIG. 12 are different from the embodiments of FIGS. 1A to 1C, in that the redistribution structure 130 further includes a dielectric layer 137 over the dielectric layer 133, and conductive lines 138 and conductive vias 139 in the dielectric layer 137. The conductive lines 138 are over the dielectric layer 133 and connected to the respective conductvie vias 135, the conductive vias 139 are over connected to the respective conductive lines 138, and the conductive pads 136 are over the dielectric layer 137 and connected to the respective conductvie vias 139.

In some embodiments, the conductive lines 138 may include similar arrangement as the conductive lines 134 discussed above with respect to FIGS. 1A to 1C. For example, the conductive lines 138 may include at least a conductive line that extends from a first position vertically above the die 110A, passing through the die-to-die region DDR between the dies 110A and 110B, to a second position vertically above the die 110B. The conductive vias 139 may include similar arrangement as the conductive via 135 discussed above with respect to FIGS. 1A to 1C. For example, the conductive vias 139 may include conductive vias vertically above the die-to-die region DDR. In some embodiments, the conductive vias 139 may also include possible variations as discussed in FIGS. 10A to 11.

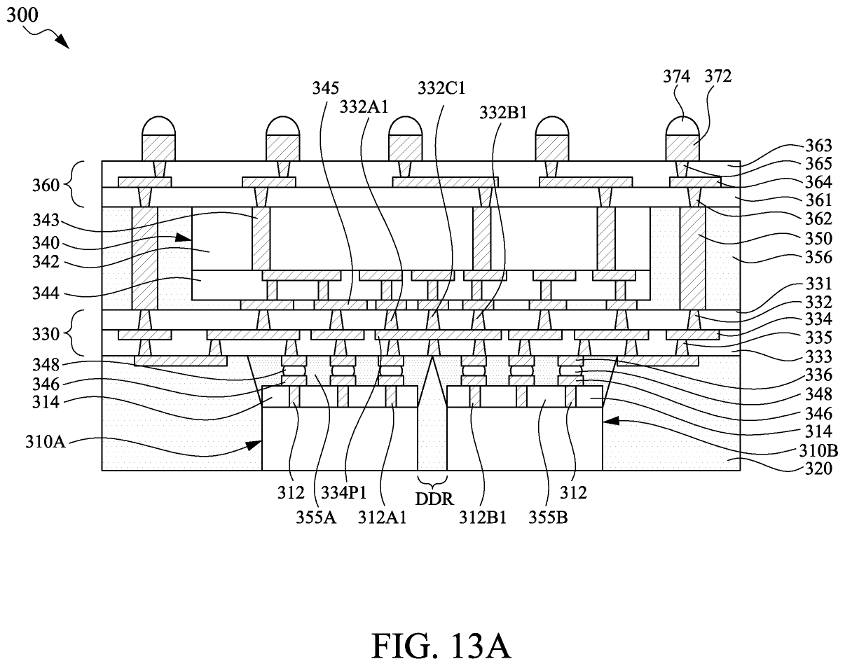

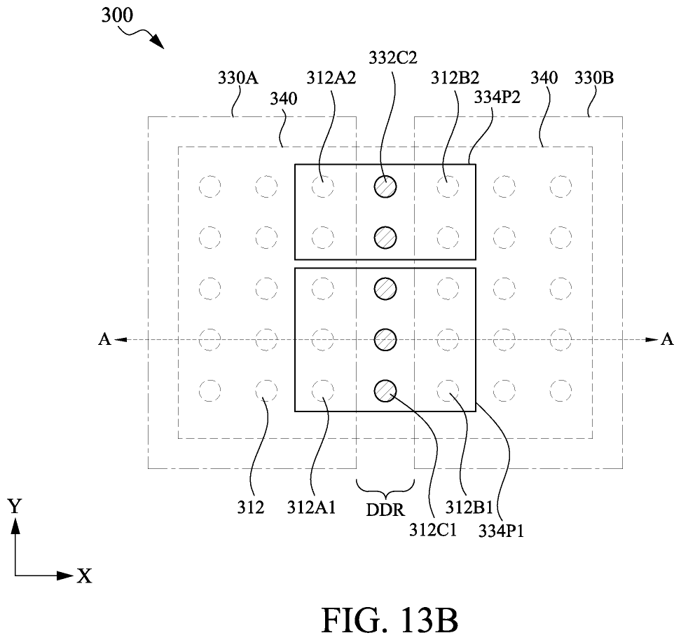

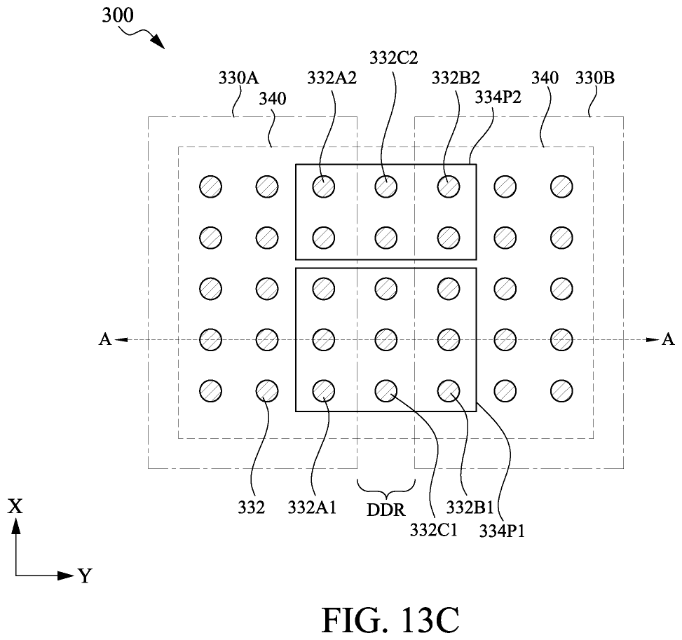

FIG. 13A illustrates a cross-sectional view of a package structure in accordance with some embodiments of the present disclosure. FIGS. 13B and 13C illustrate top views of a package structure in accordance with some embodiments of the present disclosure. In greater detail, FIG. 13A is a cross-sectional view along line A-A of FIGS. 13B and 13C. It is noted that some elements of FIG. 13A are not illustrated in FIGS. 13B and 13C for brevity.

Shown there is a package structure 300. The package structure 300 includes a plurality of dies 310A and 310B. Each of the 310A and 310B includes a semiconductor substrate 311. The dies 310A and 310B may include a plurality of conductive features 312 that are embedded in a dielectric layer 314, in which top surfaces of the conductive features 312 are exposed through the dielectric layer 314, and are substantially level with top surface of the dielectric layer 314. The structural details of the dies 310A and 310B may be similar to those described above with respect to the dies 110A and 110B, and thus relevant details will not be repeated for brevity.

Each of the dies 310A and 310B further includes under bump metallizations (UBMs) 346 along top surface of the dielectric layer 314, and are electrically connected with the conductive features 312. Bumps 348 are connected with the top surfaces of the respective UBMs 346. The materials of the UBMs 346 and the bumps 348 may be similar to those described with respect to the UBMs 146 and the bumps 148, and thus relevant details will not be repeated for brevity.

The package structure 300 further includes a redistribution structure 330 over and electrically connected with the dies 310A and 310B, respectively. The redistribution structure 330 may include a dielectric layer 331, conductive vias 332, a dielectric layer 333, conductive lines 334, conductive vias 335, and conductive pads 336. The conductive vias 332 are disposed in the dielectric layer 331. The dielectric layer 333 is in contact with the dielectric layer 331. The conductive lines 334 and the conductive vias 335 are disposed in the dielectric layer 333. The conductive lines 334 extend along bottom surface of the dielectric layer 331 and are in contact with the respective conductive vias 332. The conductive vias 335 are in contact with the respective conductive lines 334. The conductive pads 336 extend along bottom surface of the dielectric layer 333 and are in contact with the respective conductive vias 335. In some embodiments, the redistribution structure 330 includes a single layer of conductive lines (e.g., the conductive lines 334). In some embodiments, portions of the conductive pads 336 are in contact with the bumps 348, such that the redistribution structure 330 may be electrically connected with the dies 310A and 310B, respectively. Materials of the dielectric layer 331, the conductive vias 332, the dielectric layer 333, the conductive lines 334, the conductive vias 335, and the conductive pads 336 may be similar to those described with respect to the dielectric layer 131, the conductive vias 132, the dielectric layer 133, the conductive lines 134, the conductive vias 135, and the conductive pads 136, and thus relevant details will not be repeated for brevity.

The package structure 300 further includes underfill materials 355A and 355B dispensed into the gaps between the dies 310A/310B and the redistribution structure 330, respectively. The underfill materials 355A and 355B surround the UBMs 346, the bumps 348, and the conductive pads 336, and may extend along sidewalls of the dies 310A and 310B. Material of the underfill materials 355A and 355B may be similar to those described above with respect to the underfill material 155, and thus relevant details will not be repeated for brevity.

The package structure 300 further includes a molding compound 320 that encapsulates the dies 310A and 310B. The molding compound 320 may also encapsulate the underfill materials 355A and 355B, respectively. The molding compound 320 is in contact with the redistribution structure 330. In some embodiments, the molding compound 320 may also encapsulate some conductive pads 336 of the redistribution structure 330.

The package structure 300 further includes a die 340 disposed over the redistribution structure 330 and electrically connected with the redistribution structure 330. The die 340 includes a semiconductor substrate 342 and an interconnect structure 344. The interconnect structure 344 may include interconnect wirings (e.g., copper interconnect wirings) and dielectric layer stacked alternately, wherein the interconnect wirings of the interconnect structure 344 are electrically connected with the active components and/or the passive components in the semiconductor substrate 342. The interconnect structure 344 may include conductive pads 345 that are in contact and electrically connected with the respective conductive vias 332 of the redistribution structure 330, such that the die 340 can be electrically connected with the redistribution structure 330. The die 340 further includes through vias 343 penetrating through the semiconductor substrate 342 and electrically connected with the interconnect structure 344. The die 340 may be similar to the die 140 as described above, and thus relevant details will not be repeated for brevity.

The package structure 300 further includes conductive vias 350 adjacent to the die 340 and are over and in contact with the respective conductive vias 332 of the redistribution structure 330. The conductive vias 350 may be similar to the conductive vias 150 as described above, and thus relevant details will not be repeated for brevity.

The package structure 300 further includes a molding compound 356 encapsulating the conductive vias 350 and the die 340. The molding compound 356 may be similar to the molding compound 156 as described above, and thus relevant details will not be repeated for brevity.

The package structure 300 further includes a redistribution structure 360 disposed over the die 340 and the molding compound 356. In greater detail, the redistribution structure 360 is disposed along top surfaces of the molding compound 356 and the die 340. The redistribution structure 360 may include a dielectric layer 361, conductive vias 362, a dielectric layer 363, conductive lines 364, and conductive vias 365. The dielectric layer 361 is in direct contact with the molding compound 356 and the die 340. The conductive vias 362 are disposed on the dielectric layer 361 and in contact with the respective conductive vias 350 and the through vias 343 in the die 340. Materials of the dielectric layer 361, the conductive vias 362, the dielectric layer 363, the conductive lines 364, and the conductive vias 365 are similar to those described with respect to the dielectric layer 161, the conductive vias 162, the dielectric layer 163, the conductive lines 164, and the conductive vias 165, and thus relevant details will not be repeated for brevity.

The package structure 300 further includes UBMs 372 over the redistribution structure 360 and electrically connected with the respective conductive features (e.g. conductive vias 365) in the redistribution structure 360. Bumps 374 are disposed over the respective UBMs 346. The UBMs 372 and the bumps 374 may be similar to the UBMs 172 and the bumps 174 as described above, and thus relevant details will not be repeated for brevity.

Reference is made to FIGS. 13A, 13B, and 13C. In greater detail, FIG. 13B shows a structural relationship among the dies 310A and 310B, the conductive features 312 in the dies 310A and 310B, the die 340, the conductive lines 334 in the redistribution structure 330, and the conductive vias 332 in the redistribution structure 330. FIG. 13C shows a structural relationship among the dies 310A and 310B, the die 340, the conductive lines 334 in the redistribution structure 330, and the conductive vias 332 in the redistribution structure 330.

The conductive lines 334 of the redistribution structure 330 include a conductive line 334P1 and a conductive line 334P2 each overlapping both the dies 310A and 310B. Stated another way, each of the conductive lines 334P1 and 334P2 extends from a first position vertically above the die 310A, passing through the die-to-die region DDR between the dies 310A and 310B, to a second position vertically above the die 310B.

The conductive line 334P1 vertically overlaps and is electrically connected with the conductive features 312A1 in the die 310A through the respective conductive vias 335, the respective conductive pads 336, the respective bumps 348, and the respective UBMs 346. On the other hand, the conductive line 334P1 vertically overlaps and is electrically connected with the conductive features 312B1 in the die 310B through the respective conductive vias 335, the respective conductive pads 336, the respective bumps 348, and the respective UBMs 346. Similarly, the conductive line 334P2 vertically overlaps and is electrically connected with the conductive features 312A2 in the die 310A through the respective conductive vias 335, the respective conductive pads 336, the respective bumps 348, and the respective UBMs 346. On the other hand, the conductive line 334P2 vertically overlaps and is electrically connected with the conductive features 312B2 in the die 310B through the respective conductive vias 335, the respective conductive pads 336, the respective bumps 348, and the respective UBMs 346. That is, the dies 310A and 310B may be electrically connected with each other through the conductive line 334P1, the conductive vias 335, the conductive pads 336, the bumps 348, and the UBMs 346. Alternatively, the dies 310A and 310B may be electrically connected with each other through the conductive line 134P2, the conductive vias 335, the conductive pads 336, the bumps 348, and the UBMs 346.

The conductive features 312A1 and 312A2 in the die 310A are arranged along a first direction (e.g., Y-direction), and the conductive features 312B1 and 312B2 in the die 310B are arranged along the first direction (e.g., Y-direction). In some embodiments, the conductive features 312 in the die 310A may include several rows of conductive features 312 arranged along a second direction (e.g., X-direction), and the conductive features 312A1 and 312A2 in the die 310A are at a row that is closest to the die 310B. Similarly, the conductive features 312 in the die 310B may include several rows of conductive features 312 arranged along a second direction (e.g., X-direction), and the conductive features 312B1 and 312B2 in the die 310B are at a row that is closest to the die 310A. It is understood that the first direction (e.g., Y-direction) is substantially perpendicular to the second direction (e.g., X-direction).

Although not illustrated, it is noted that the conductive pads 336, the bumps 348, and the UBMs 346 may also include a same arrangement as the conductive features 312 discussed with respect to FIG. 13B. That is, the conductive pads 336, the bumps 348, and the UBMs 346 may also include portions that correspond to the conductive features 312A1, 312A2, 312B1, and 312B2 as discussed in FIG. 13B. Accordingly, relevant details will not be repeated for brevity.

With respect to the conductive vias 332, the conductive vias 332 may include conductive vias 332A1 vertically above the conductive line 334P1 and overlapping the die 110A, and conductive vias 332A2 vertically above the conductive line 134P2 and overlapping the die 310A, in which the conductive vias 332A1 and 332A2 may be arranged in a row along the first direction (e.g., Y-direction). The conductive vias 332 also include conductive vias 332B1 vertically above the conductive line 334P1 and overlapping the die 310B, and conductive vias 332B2 vertically above the conductive line 334P2 and overlapping the die 310B, in which the conductive vias 332B1 and 332B2 may be arranged in a row along the first direction (e.g., Y-direction).

Moreover, the conductive vias 332 also include conductive vias 332C1 vertically above the conductive line 334P1 and overlapping the die-to-die region DDR, and conductive vias 332C2 vertically above the conductive line 334P2 and overlapping the die-to-die region DDR, in which the conductive vias 332C1 and 332C2 may be arranged in a row along the first direction (e.g., Y-direction). In some embodiments, the conductive vias 332C1 and 332C2 do not overlap the dies 310A and 310B. In some embodiments, the number of the conductive vias 332C1 is different from the number of the conductive vias 332C2. For example, in the illustrated embodiments, there are three conductive vias 332C1 and two conductive vias 332C2, while the disclosure is not limited thereto. In other embodiments, the number of the conductive vias 332C1 may be the same as the number of the conductive vias 332C2.

In some embodiments, the conductive vias 332C1 are substantially aligned with the conductive vias 332A1 and 332B1 along the second direction (e.g., X-direction), and the conductive vias 332C2 are substantially aligned with the conductive vias 332A2 and 332B2 along the second direction (e.g., X-direction).

Although not illustrated, it is noted that the conductive pads 345 may also include a same arrangement as the conductive vias 332 discussed with respect to FIG. 13C. That is, the conductive pads 345 may also include portions that correspond to the conductive vias 332A1, 332A2, 332B1, 332B2, 332C1 and 332C2 as discussed in FIG. 13C. Accordingly, relevant details will not be repeated for brevity.

Based on the above discussion, it can be seen that the dies 310A and 310B (at the bottom side of the package structure 300) may be electrically connected with the bumps 374 (at the top side of the package structure 300) through several conductive structures, such as the conductive features 312, the bumps 348, the redistribution structure 330, the die 340, and the redistribution structures 360. Accordingly, electrical signal may be conducted from an external device down to the dies 310A and 310B. However, as device scale getting smaller and smaller, electromigration (EM) issue may likely occur in the package structure, resulting in a deteriorated performance to the package structure. Embodiments of the present disclosure provide a package structure by forming additional conductive vias (e.g., conductive vias 332C1 and 332C2) vertically overlapping a die-to-die region between the dies (e.g., the dies 310A and 310B). The additional conductive vias may provide more current paths in the package structure, so as to address the electromigration issue. As a result, performance of the package structure may be improved.

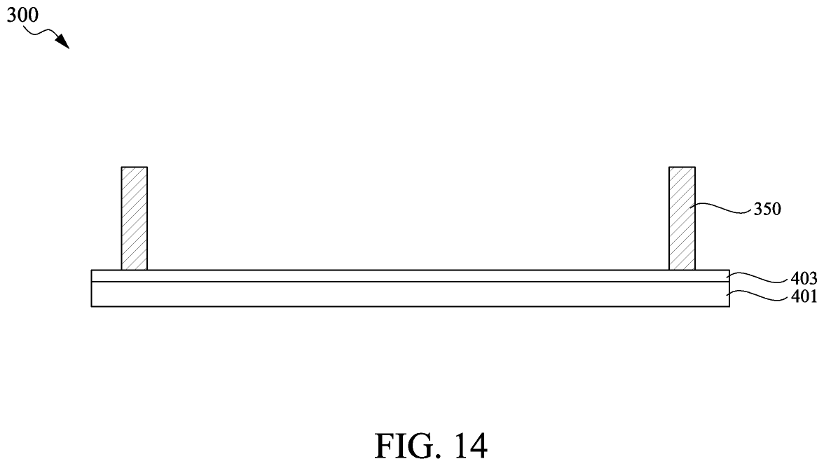

FIGS. 14 to 21 illustrate a method in various stages of forming a package structure in accordance with some embodiments of the present disclosure.

Reference is made to FIG. 14. Shown there is a carrier substrate 401, and a release film 403 is formed over the carrier substrate 401. The carrier substrate 401 and the release film 403 may be similar to the carrier substrate 201 and the release film 203 as described above, and thus relevant details will not be repeated for brevity.

Conductive vias 350 are formed over the release film 403. In some embodiments, the conductive vias 350 may be formed by initially depositing a photoresist (not shown) over the release film 403. Once the photoresist has been formed, it may be patterned to form openings that expose portions of the release film 403 that are located where the conductive vias 350 will subsequently be formed. Once the photoresist has been patterned, a conductive material may be deposited in the openings and over the release film 403. The conductive material may be formed through a deposition process such as electroplating, electroless plating, or the like. However, while the material and methods discussed are suitable to form the conductive material, these are merely examples. Any other suitable materials or any other suitable processes of formation, such as CVD or PVD, may also be used to form the conductive vias 350. Once the conductive material has been formed, the photoresist may be removed through a suitable removal process such as an ashing process or a chemical stripping process, such as using oxygen plasma or the like.

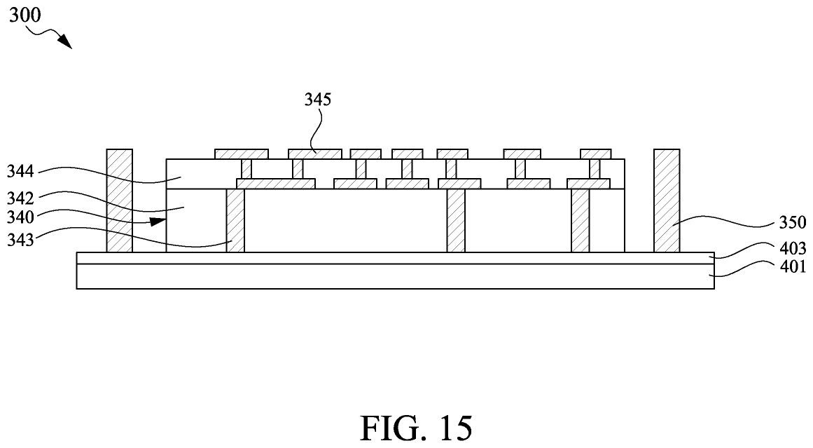

Reference is made to FIG. 15. A die 340 is attached to the release film 403. In some embodiments, the die 340 may be placed on the release film 403, for example, using e.g., a pick-and-place process.

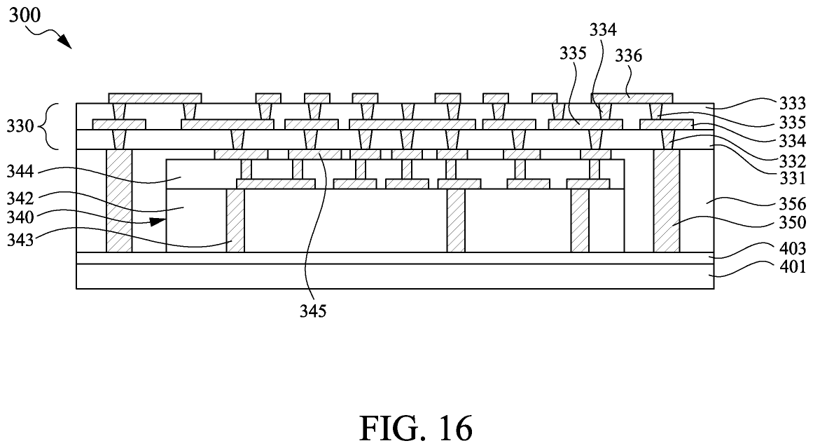

Reference is made to FIG. 16. A molding compound 356 is formed to encapsulate of the die 340 and the conductive vias 350. The encapsulation may be performed using a molding device or the molding compound 356 may be deposited using another technique.

A planarization process is then performed on the molding compound 356. The planarization process may be performed, e.g., using a mechanical grinding process, a chemical mechanical polishing (CMP) process, or the like. The planarization process removes excess portions of molding compound 356 and exposes the conductive vias 350. The planarization process may also expose the conductive pads 345 of the die 340. After the planarization process is complete, the conductive vias 350 and/or the conductive pads 345 may have top surfaces level with a surface of the molding compound 356.

A redistribution structure 330 is then formed over the molding compound 356 and the die 340. The formation method of the redistribution structure 330 may be similar to those described above with respect to the redistribution structure 130, and thus relevant details will not be repeated for brevity.

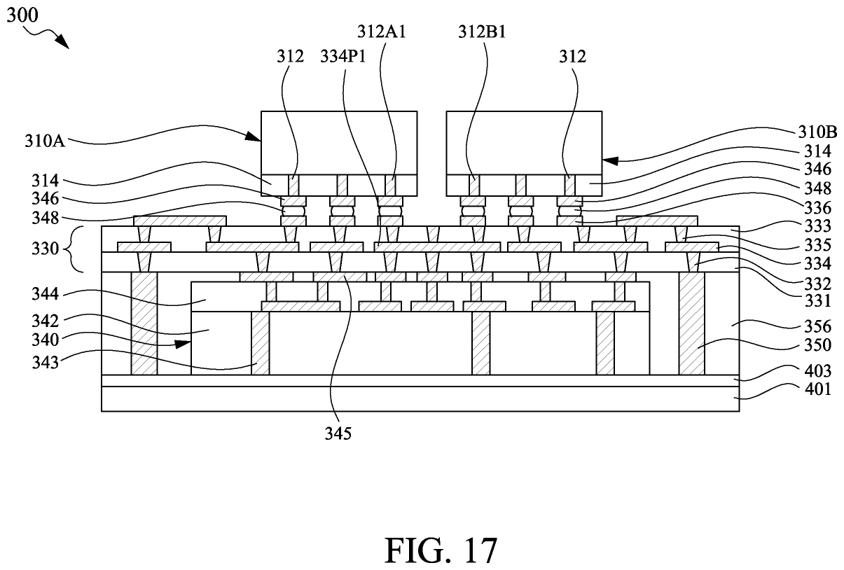

Reference is made to FIG. 17. Die 310A and 310B are attached to the redistribution structure 330. In some embodiments, the bumps 348 may first be formed on the UBMs 346 of the dies 310A and 310B. Then, the dies 310A and 310B may be placed on the redistribution structure 330, for example, using e.g., a pick-and-place process. In some embodiments, once the bumps 348 on the UBMs 346 of the dies 310A and 310B are attached on and are in physical contact with the corresponding conductive pads 336 of the redistribution structure 330, a reflow process may be performed to bond the bumps 348 to the conductive pads 336 of the redistribution structure 330 and thus attach the dies 310A and 310B to the redistribution structure 330.

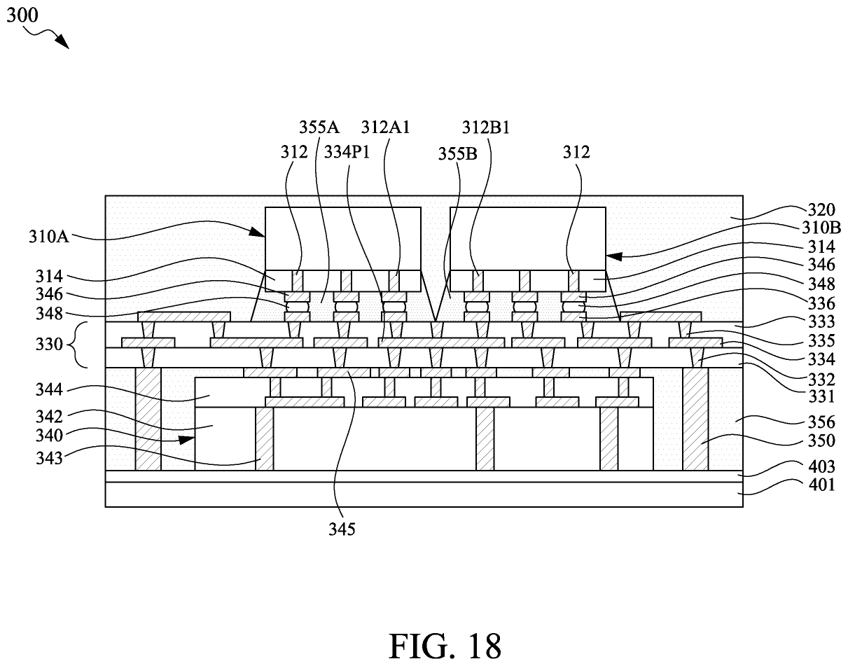

Reference is made to FIG. 18. Once the dies 310A and 310B are attached to the redistribution structure 330, underfill materials 355A and 355B can be deposited in the gap between 310A and 310B and the redistribution structure 330. A molding compound 320 is formed to encapsulate of the 310A and 310B. The encapsulation may be performed using a molding device or the molding compound 156 may be deposited using another technique.

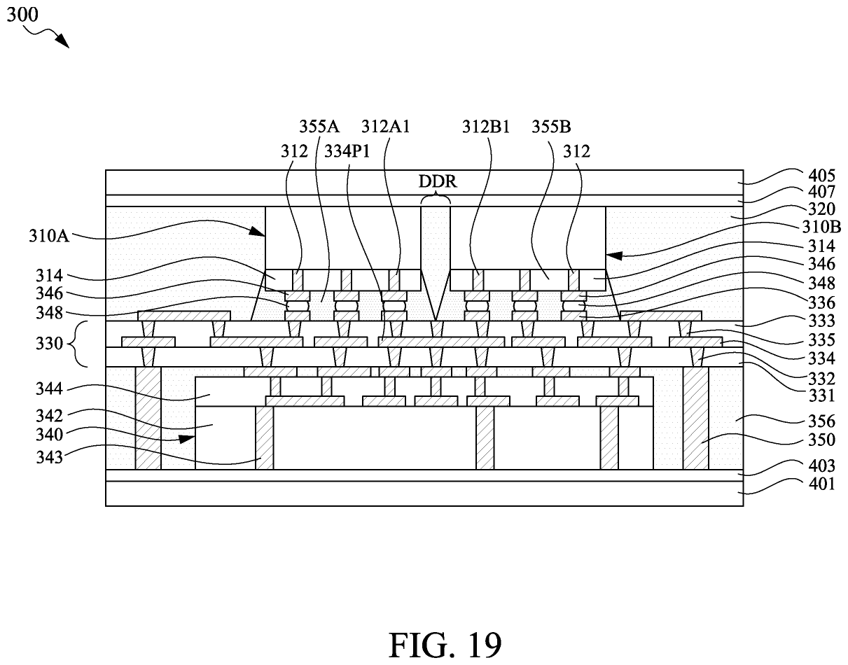

Reference is made to FIG. 19. The structure of FIG. 18 is flipped over, for example, by 180 degrees, and the structure is attached on a release film 407 on a carrier substrate 405. The carrier substrate 405 and the release film 407 may be similar to the carrier substrate 201 and the release film 203 as described above, and thus relevant details will not be repeated for brevity.

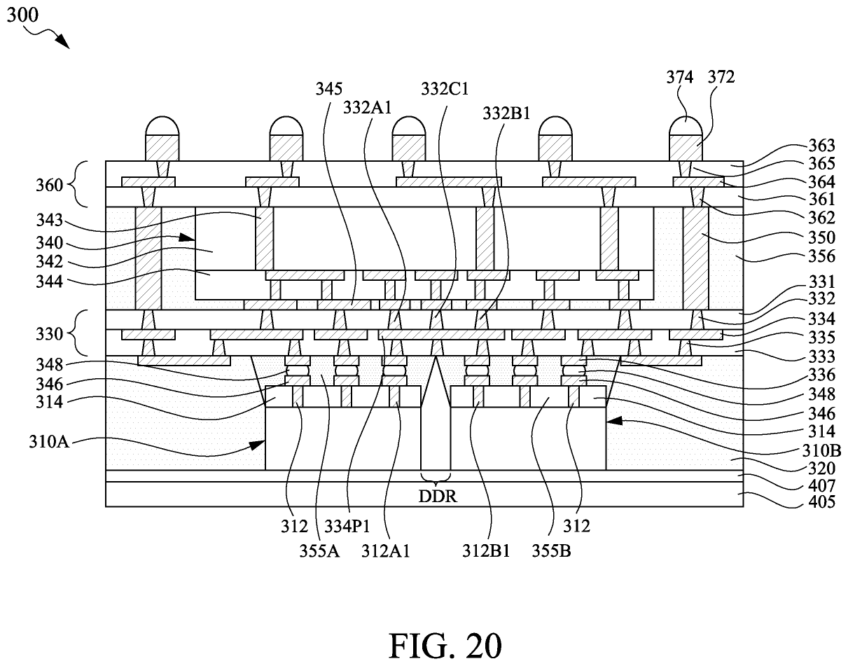

Reference is made to FIG. 20. The carrier substrate 401 and the release film 403 are removed, such that the conductive vias 350, the through vias 343 of the die 340, and the molding compound 356 are exposed.

A redistribution structure 360 is then formed over the molding compound 356 and the die 340. UBMs 372 are then formed over the redistribution structure 360, and bumps 374 are then formed over the UBMs 372. The formation methods of the redistribution structure 360, the UBMs 372, and the bumps 374 may be similar to those described above with respect to the redistribution structure 160, the UBMs 172, and the bumps 174, and thus relevant details will not be repeated for brevity.

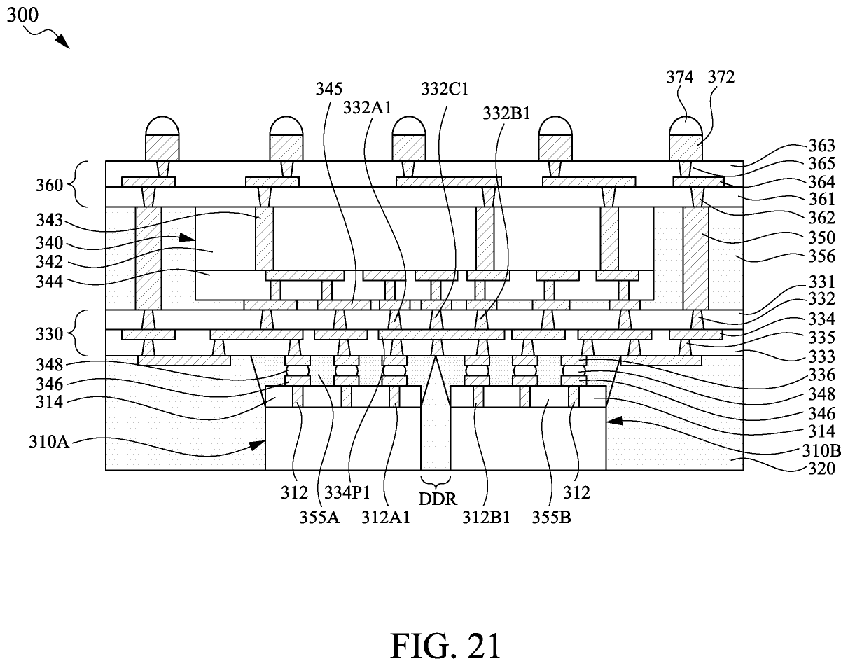

Reference is made to FIG. 21. The carrier substrate 405 is de-bonded from the molding compound 320. In some embodiments, the de-bonding process includes projecting a light such as a laser light or an UV light on the release film 407 over the carrier substrate 405 so that the release film 407 decomposes under the heat of the light and the carrier substrate 405 can be removed.

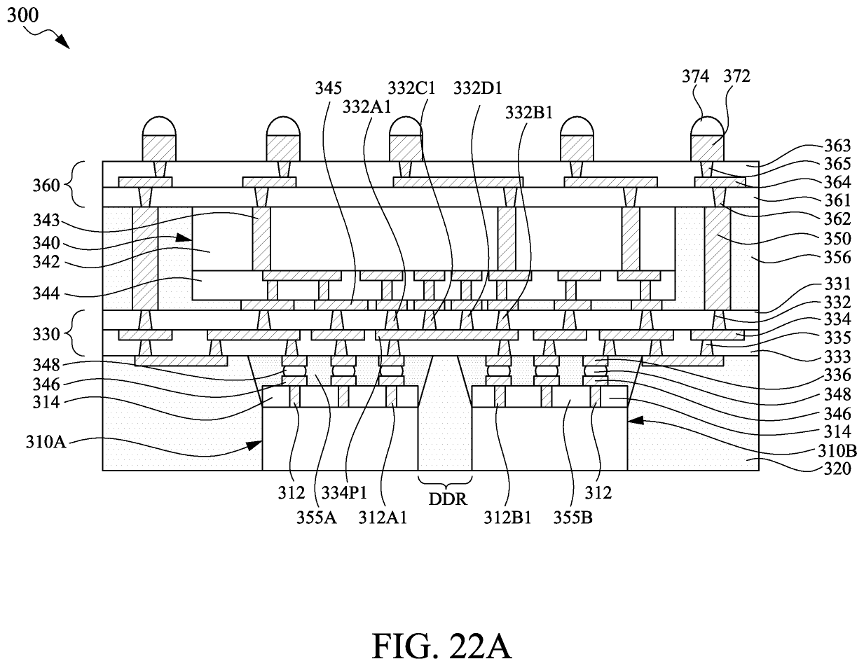

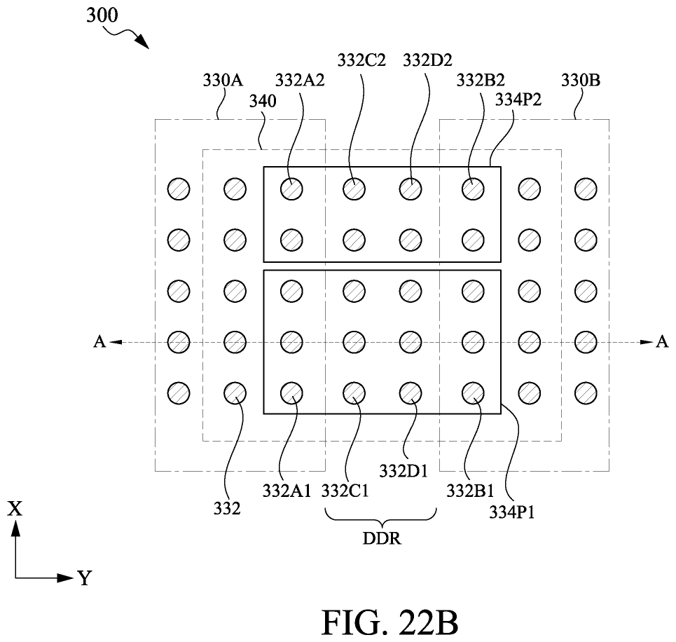

FIG. 22A illustrates a cross-sectional view of a package structure in accordance with some embodiments of the present disclosure. FIG. 22B illustrates a top view of a package structure in accordance with some embodiments of the present disclosure. In greater detail, FIG. 22A is a cross-sectional view along line A-A of FIG. 22B. It is noted that some elements of FIG. 22A are not illustrated in FIG. 22B for brevity. FIG. 22A is similar to the cross-sectional view of FIG. 13A, and FIG. 22B is a top view similar to FIG. 13C, thus similar elements are labeled the same and will not be repeated again.

The embodiments of FIGS. 22A and 22B are different from the embodiments of FIGS. 13A to 13C, in that the conductive vias 332 further include a row of conductive vias 332D1 and 332D2 vertically above the die-to-die region DDR. In greater detail, the conductive vias 332D1 are vertically above the conductive line 334P1, and the conductive vias 332D2 are vertically above the conductive line 334P2, respectively. In some embodiments, the row of conductive vias 332C1 and 332C2 and the row of conductive vias 332D1 and 332D2 are arranged along the second direction (e.g. X-direction). It is noted that, the number of rows of the conductive vias 332 at the die-to-die region DDR may depend on the area of the die-to-die region DDR. For example, more rows of the conductive vias 332 may also be applied for a larger die-to-die region DDR. The increasing number of conductive vias 332 may also be helpful to address the electromigration issue.

Although not illustrated, it is noted that the conductive pads 345 may also include a similar arrangement as the conductive vias 332 discussed with respect to FIGS. 22A and 22B. That is, the conductive pads 345 may also include portions that correspond to the conductive vias 332A1, 332A2, 332B1, 332B2, 332C1, 332C2, 332D1, and 332D2 as discussed in FIG. 22B. Accordingly, relevant details will not be repeated for brevity.

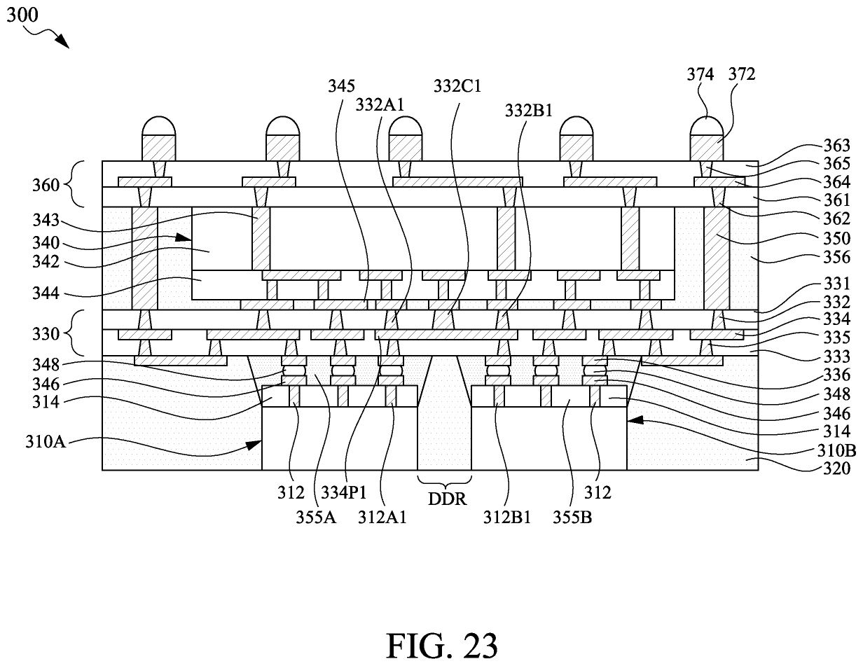

FIG. 23 illustrates a cross-sectional view of a package structure in accordance with some embodiments of the present disclosure. FIG. 23 is similar to the cross-sectional view of FIG. 13A, thus similar elements are labeled the same and will not be repeated again.

The embodiments of FIG. 23 are different from the embodiments of FIGS. 13A to 13C, in that the size of the conductive vias 332C1 (and 332C2, see FIG. 13C) vertically above the die-to-die region DDR may be different from the size of the conductive vias 332 outside the die-to-die region DDR. For example, the size (e.g., diameter or lateral width) of the conductive vias 332C1 and 332C2 may be greater than the conductive vias 332 that are vertically above the dies 310A and 310B. The increasing size of conductive vias 332C1 and 332C2 may provide enlarged current path, and may also be helpful to address the electromigration issue.

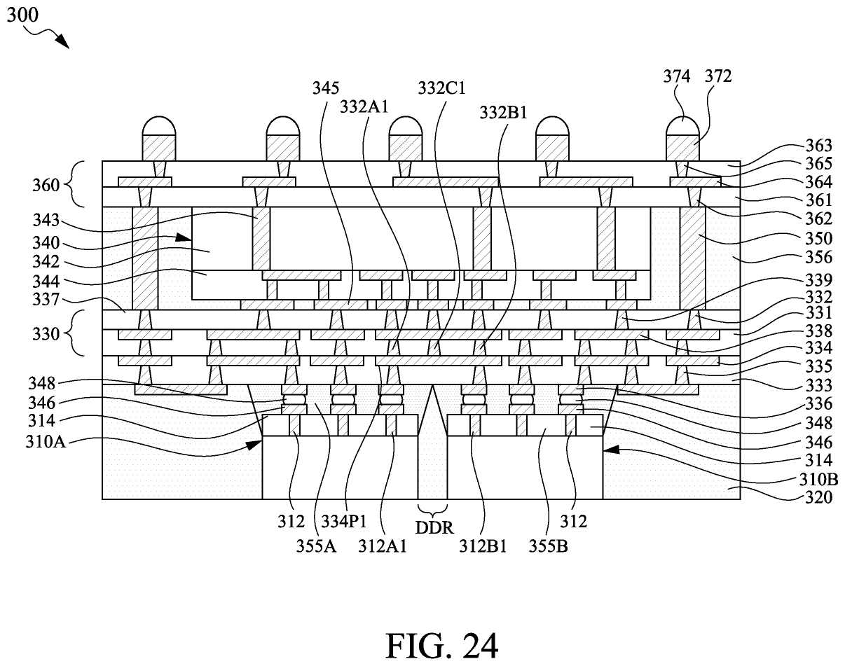

FIG. 24 illustrates a cross-sectional view of a package structure in accordance with some embodiments of the present disclosure. FIG. 24 is similar to the cross-sectional view of FIG. 13A, thus similar elements are labeled the same and will not be repeated again.

The embodiments of FIG. 24 are different from the embodiments of FIGS. 13A to 13C, in that the redistribution structure 330 further includes a dielectric layer 337 over the dielectric layer 331, conductive vias 139 in the dielectric layer 337, and conductive lines 138 along surface of the dielectric layer 337.

In some embodiments, the conductive lines 338 may include similar arrangement as the conductive lines 334 discussed above with respect to FIGS. 13A to 13C. For example, the conductive lines 338 may include at least a conductive line that extends from a first position vertically above the die 310A, passing through the die-to-die region DDR between the dies 310A and 310B, to a second position vertically above the die 310B. The conductive vias 339 may include similar arrangement as the conductive via 332 discussed above with respect to FIGS. 13A to 13C. For example, the conductive vias 339 may include conductive vias vertically above the die-to-die region DDR. In some embodiments, the conductive vias 339 may also include possible variations as discussed in FIGS. 22A to 23.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a package structure by forming additional conductive vias and bumps overlapping a die-to-die region between the dies. The additional conductive vias and bumps may provide more current paths in the package structure, so as to address the electromigration issue. As a result, performance of the package structure may be improved.

In some embodiments of the present disclosure, a package structure includes a first die and a second die adjacent to the first die. A redistribution structure is above and electrically connected with the first and second die. The redistribution structure includes a first conductive line electrically connecting the first die to the second die, and a first conductive via in contact with the first conductive line and overlapping a die-to-die region between the first and second dies. A third die is over and electrically connected with the redistribution structure. An external connector is over electrically connected with the third die.

In some embodiments, the first conductive line overlaps the first die and the second die.

In some embodiments, the third die is electrically connected with the redistribution structure through a plurality of bumps, and one of the plurality of bumps is electrically connected with the first conductive via and overlapping the die-to-die region between the first and second dies.

In some embodiments, the package structure further includes a second conductive via in contact with the first conductive line and overlapping the die-to-die region between the first and second dies.

In some embodiments, the first and second dies are arranged along a first direction, and the first and second conductive vias are arranged along a second direction substantially perpendicular to the first direction.

In some embodiments, the package structure further includes a second conductive via conductive via in contact with the first conductive line and overlapping the first die.

In some embodiments, the package structure further includes a third conductive via conductive via in contact with the first conductive line and overlapping the second die.

In some embodiments, the second conductive via is wider than the first conductive via in a cross-sectional view.

In some embodiments of the present disclosure, a package structure includes a first die and a second die arranged along a first direction. A redistribution structure is above and electrically connected with the first and second die. The redistribution structure includes a first conductive line and a second conductive line over the first and second dies and arranged along a second direction substantially perpendicular first direction, and first conductive vias in contact with the first conductive line and second conductive vias in contact with the second conductive line, respectively. In a top view the first conductive vias and the second conductive vias are located at a die-to-die region between the first and second dies. A third die is over and electrically connected with the redistribution structure. An external connector is over electrically connected with the third die.

In some embodiments, the first conductive vias and the second conductive vias are arranged along the second direction.

In some embodiments, the package structure further includes third conductive vias in contact with the first conductive line and overlapping the first die, wherein the third conductive vias and the first and second conductive vias are at a same level.

In some embodiments, in the top view, the third conductive vias are substantially aligned with the first and second conductive vias along the first direction.

In some embodiments, the first and second conductive lines overlap both the first and second dies.

In some embodiments, the package structure further includes bumps between the redistribution structure and the third die and are electrically connected with the first and second conductive vias, wherein in the top view the bumps are located at the die-to-die region between the first and second dies.

In some embodiments, a number of the first conductive vias is different from a number of the second conductive vias.

In some embodiments of the present disclosure, a method includes forming a first molding compound encapsulating first and second dies; forming a first redistribution structure over the first molding compound, wherein the first redistribution structure comprises a first conductive line electrically connecting the first die to the second die, and a first conductive via in contact with the first conductive line and overlapping a die-to-die region between the first and second dies; forming a third die over the first redistribution structure; forming a second molding compound encapsulating the third die; and forming a second redistribution structure over the second molding compound.

In some embodiments, the third die overlaps both the first and second dies.

In some embodiments, forming the third die over the first redistribution structure is performed such that bumps on the third die are attached to the first redistribution structure, wherein one of the bumps overlaps the die-to-die region between the first and second dies.

In some embodiments, the one of the bumps overlaps the first conductive via.

In some embodiments, the method further includes placing the first and second dies on a carrier substrate prior to forming the first molding compound; and removing the carrier substrate after forming the second redistribution structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a first die and a second die adjacent to the first die;
a redistribution structure above and electrically connected with the first and second die, wherein the redistribution structure comprises:
a first conductive line electrically connecting the first die to the second die; and
a first conductive via in contact with the first conductive line and overlapping a die-to-die region between the first and second dies;
a third die over and electrically connected with the redistribution structure; and
an external connector over electrically connected with the third die.

2. The package structure of claim 1, wherein the first conductive line overlaps the first die and the second die.

3. The package structure of claim 1, wherein the third die is electrically connected with the redistribution structure through a plurality of bumps, and one of the plurality of bumps is electrically connected with the first conductive via and overlapping the die-to-die region between the first and second dies.

4. The package structure of claim 1, further comprising a second conductive via in contact with the first conductive line and overlapping the die-to-die region between the first and second dies.

5. The package structure of claim 4, wherein the first and second dies are arranged along a first direction, and the first and second conductive vias are arranged along a second direction substantially perpendicular to the first direction.

6. The package structure of claim 1, further comprising a second conductive via conductive via in contact with the first conductive line and overlapping the first die.

7. The package structure of claim 6, further comprising a third conductive via conductive via in contact with the first conductive line and overlapping the second die.

8. The package structure of claim 6, wherein the second conductive via is wider than the first conductive via in a cross-sectional view.

9. A package structure, comprising:
a first die and a second die arranged along a first direction;
a redistribution structure above and electrically connected with the first and second die, wherein the redistribution structure comprises:
a first conductive line and a second conductive line over the first and second dies and arranged along a second direction substantially perpendicular first direction; and
first conductive vias in contact with the first conductive line and second conductive vias in contact with the second conductive line, respectively, wherein in a top view the first conductive vias and the second conductive vias are located at a die-to-die region between the first and second dies;
a third die over and electrically connected with the redistribution structure; and
an external connector over electrically connected with the third die.

10. The package structure of claim 9, wherein the first conductive vias and the second conductive vias are arranged along the second direction.

11. The package structure of claim 9, further comprising third conductive vias in contact with the first conductive line and overlapping the first die, wherein the third conductive vias and the first and second conductive vias are at a same level.

12. The package structure of claim 11, wherein in the top view, the third conductive vias are substantially aligned with the first and second conductive vias along the first direction.

13. The package structure of claim 9, wherein the first and second conductive lines overlap both the first and second dies.

14. The package structure of claim 9, further comprising bumps between the redistribution structure and the third die and are electrically connected with the first and second conductive vias, wherein in the top view the bumps are located at the die-to-die region between the first and second dies.

15. The package structure of claim 9, wherein a number of the first conductive vias is different from a number of the second conductive vias.

16. A method, comprising:
forming a first molding compound encapsulating first and second dies;
forming a first redistribution structure over the first molding compound, wherein the first redistribution structure comprises:
a first conductive line electrically connecting the first die to the second die; and
a first conductive via in contact with the first conductive line and overlapping a die-to-die region between the first and second dies;
forming a third die over the first redistribution structure;
forming a second molding compound encapsulating the third die; and
forming a second redistribution structure over the second molding compound.

17. The method of claim 16, wherein the third die overlaps both the first and second dies.

18. The method of claim 16, wherein forming the third die over the first redistribution structure is performed such that bumps on the third die are attached to the first redistribution structure, wherein one of the bumps overlaps the die-to-die region between the first and second dies.

19. The method of claim 18, wherein the one of the bumps overlaps the first conductive via.

20. The method of claim 16, further comprising:
placing the first and second dies on a carrier substrate prior to forming the first molding compound; and
removing the carrier substrate after forming the second redistribution structure.
